(19) United States
(12) Patent Application Publication
(10) Pub. No.: US 2013/0135505 A1
(43) Pub. Date: May 30, 2013

(54) SOLID-STATE IMAGING DEVICE AND IMAGING APPARATUS

(71) Applicant: Panasonic Corporation, Osaka (JP)

(72) Inventor: Shinji YOSHIDA, Shiga (JP)

(73) Assignee: PANASONIC CORPORATION, Osaka (JP)

(21) Appl. No.: 13/749,192

(22) Filed: Jan. 24, 2013

Related U.S. Application Data
(63) Continuation of application No. PCT/JP2011/004045, filed on Jul. 15, 2011.

(30) Foreign Application Priority Data
Aug. 4, 2010 (JP) 2010-175664

(51) Int. Cl. H04N 5/335; H01L 31/0264

(52) U.S. Cl. CPC H04N 5/335; H01L 31/0264
USPC 348/311; 257/43

(57) ABSTRACT

A solid-state imaging device includes an imaging region having pixel units two-dimensionally arranged, each of the pixel units including a photoelectric converting device formed on a semiconductor substrate. The solid-state imaging device includes: an interlayer film made of a dielectric and formed above the photoelectric converting device; a light attenuation filter which is formed above the interlayer film for each of the pixel units or for each of pixel blocks, and changes a transmittance of light when a voltage is applied to the light attenuation filter, the pixel blocks each including a plurality of the pixel units; and a selecting transistor which is formed in the semiconductor substrate for each of the light attenuation filters, and connects or disconnects a path for applying the voltage to the light attenuation filter.

### CROSS REFERENCE TO RELATED APPLICATIONS

This is a continuation application of PCT International Application No. PCT/JP2011/004045 filed on Jul. 15, 2011, designating the United States of America, which is based on and claims priority of Japanese Patent Application No. 2010-175664 filed on Aug. 4, 2010. The entire disclosures of the above-identified applications, including the specifications, drawings and claims are incorporated herein by reference in their entirety.

### FIELD

The present invention relates to a solid-state imaging device and an imaging apparatus included in a digital still camera.

### BACKGROUND

When images are captured with a digital still camera, an external neutral density (ND) filter and a mechanical aperture are used to adjust an amount of light depending on the lighting intensity of an object and a capturing location. Since both the filter and the aperture operate as separate devices from a solid-state imaging device, downsizing a camera can be difficult. Hence digital security cameras and cell-phone cameras, in particular, are not equipped with the above-described external ND filters and mechanical apertures.

Moreover, pixel sizes are becoming smaller in response to requests for finer images and smaller devices. Thus, photodiodes are downsized, and the saturation lighting intensity in imaging decreases. Inevitably, the photodiodes are saturated when an image is captured outdoors under high lighting intensity such as a sunny day. As a result, the captured image appears white. Such whiteness, or “flared highlights”, is a problem of the downsized photodiodes. In particular, when both an area with high lighting intensity and an area with low lighting intensity are included in a single angle of view, the downsized photodiode faces an extreme challenge-imaging, showing contrast and keeping both signals for the high lighting intensity and the low lighting intensity from saturating. Consequently, it is difficult for the downsized diode to capture an image under high lighting intensity without a mechanism for adjusting a light amount.

Patent Literature 1 discloses a solid-state imaging device which includes (i) a solid-state imaging element embedded in a camera having no mechanical aperture, and (ii) a light amount adjusting unit which is provided in parallel with an imaging area of the solid-state imaging element and integrated into a package, and controls transmitted light by applying a current.

FIG. 14 is a cross-sectional view showing a structure of a conventional solid-state imaging device described in Patent Literature 1, A solid-state imaging device 508 illustrated in FIG. 14 includes a charge coupled device (CCD) package 502 having a COD element 501 whose imaging area is bonded, and a light amount adjusting unit 503 embedded in the CCD package 502. The light amount adjusting unit 503 is a well-known electrochromic element including the following constitutional elements formed in a unit with a frame 503a: a glass plate 504, a transparent conductive film 505, an electrochromic film 506, and an electrolytic film 507. The electrochromic film 506 turns gray when voltages are applied from terminals A and B, and becomes colorless and transparent when a direct-current voltage of a reversed polarity is applied. This phenomenon is employed to adjust the transmitted light intensity of the light amount adjusting unit 503. As described above, the solid-state imaging device 508 uses the electrochromic element as a light adjusting unit as described above to invariably change the transmittance of light when a voltage is applied thereto. Such a structure allows the imaging device to capture an image with the light amount adjusted even under high lighting intensity. Moreover, the electrochromic element allows the use of as thin film instead of a mechanical feature such as a motor, which contributes to downsizing a camera.

### CITATION LIST

### Patent Literature

[PTL 1] Japanese Unexamined Patent Application Publication No. 09-129859

### SUMMARY

### Technical Problem

The structure of the solid-state imaging device disclosed in Patent Literature 1, however, is no more than uniformly reducing a light amount within an angle of view, Inevitably, the dynamic rage becomes lower within the same angle of view. When there are an object with high brightness and an object with low brightness within the same angle of view, for example, a filter including the electrochromic element in FIG. 14 limits the amount of transmitted light. Accordingly, the signal intensity of the object with low brightness reduces, and the deterioration in S/N is unavoidable.

In addition, according to the structure of the solid-state imaging device in Patent Literature 1, the glass plate 504 that seals the light amount adjusting unit 503 is provided on the light axis separately from the CCD element 501. Such a structure causes problems of creating a false image and a false signal, referred to as ghost and lens flare, due to multiple reflections of light between the surface of the CCD element 501 and the light amount adjusting unit 503, which results in deterioration in image quality.

Hence required is a solid-state imaging device which reduces the above ghost and lens flare, and has a wide dynamic range that makes imaging possible under high lighting intensity.

The present invention is conceived in view of the above problems and aims to provide an object to implement a solid-state imaging device which is capable of adjusting a light amount without an aperture mechanism and imaging with a wide dynamic range under high lighting intensity.

### Solution to Problem

In order to solve the above problems, a solid-state imaging device according to an aspect of the present invention includes an imaging region having pixel units two-dimensionally arranged, each of the pixel units including a photoelectric converting device formed on a semiconductor substrate. The solid-state imaging device includes: an interlayer film which is made of a dielectric and formed above the photoelectric converting device; a light attenuation filter which is formed above the interlayer film for each of the pixel units or for each of pixel blocks, and changes a transmittance of light when a voltage is applied to the light attenuation filter, the pixel blocks each including a plurality of the pixel units; and a switching transistor which is formed in the semiconductor substrate for each of the light attenuation filters, and connects or disconnects a path for applying the voltage to the light attenuation filter.

According to the aspect, a light attenuation filter which is capable of adjusting a transmittance is provided for each pixel unit or for each pixel block. Thus an exposure requirement can be set for each pixel unit or for each pixel block. Hence when both an object having high brightness and an object having low brightness are included in a single angle of view, the amount of transmitting light can be controlled for each pixel unit or for each pixel block. Such a feature contributes to implementing a wide dynamic range which successfully expresses clear contrast of the object having low brightness, and keeps a pixel region having high luminance from being saturated.

Furthermore, the light attenuation filter is formed, for each pixel unit or for each pixel block, above the photoelectric converting unit via the interlayer films 24 made of a dielectric. Consequently, the above structure makes it possible to reduce ghost and lens flare caused by multiple reflections of light.

Preferably, the light attenuation filter includes: a lower transparent electrode which is stacked on the interlayer film made of the dielectric; a solid electrolyte layer and an active material layer which are stacked over the lower transparent electrode; and an upper transparent electrode which is stacked on one of the solid electrolyte layer and the active material layer whichever is provided above, wherein the solid electrolyte layer is made of insulating dielectric, and attracts and releases ions when the voltage is applied to the lower transparent electrode and the upper transparent electrode, and, in the active material layer, an absorbing spectrum changes according to the attraction and the release of the ions caused by the application of the voltage.

The feature makes it possible to produce a thinner light attenuation filter. Consequently such a structure allows the implementation of a small solid-state imaging device which can obtain finer images.

Preferably, the active material layer is an amorphous film made of one of WO₃, MoO₃, and IrO₂.

Such a feature makes it possible to perform the color conversion of a thin film in transparent and deep blue, which contributes to implementing a small solid-state imaging device having a wide dynamic range.

Preferably, the solid electrolyte layer includes hydrogen and is made of at least one of ZrO₂, Ta₂O₅, Cr₂O₃, V₂O₅, SiO₃, Nb₂O₅, and HfO₂.

Since those materials use hydrogen as a medium for ion conduction, ions are easily introduced to solid electrolytes. Besides, the radius of a Hydrogen ion is small. Such features contribute to high-speed switching of the transmittance of the light attenuation filter. Consequently, a high-speed solid-state imaging device can be implemented at a low cost.

Preferably, the solid electrolyte layer is made of one of metal oxides, such as ZrO₂, Ta₂O₅, Cr₂O₃, V₃O₅, Nb₂O₅, and HfO₂, the metal oxides including at least one of Li, Na, and Ag.

Since the above feature allows a non-volatile element, such as Li, Na, or Ag, to be used as an ion conduction medium, the ions can be introduced to a solid electrolyte in a quantitative manner. Consequently, variation in transmittance of the light attenuation filter is reduced and the transmittance is controlled more accurately. This contributes to implementing a solid-state imaging device having a high yield and a wide dynamic range.

Preferably, the light attenuation filter further includes a thin insulating layer provided between the solid electrolyte layer and the active material layer, and the thin insulating layer is made of one of SiO₂, SiON, and SiN.

Such a feature allows a thin insulating layer to be provided between the solid electrolyte layer and the active material layer to reduce the leak current of an electrochromic element. Consequently, the feature contributes to reducing variation in transmittance in a plane of the light attenuation filter, securing repeatability of the transmittance, and maintaining the transmittance for a longer period. This makes it possible to implement a solid-state imaging device including a high-yield and high performance light attenuation filter.

Preferably, the solid-state imaging device is placed in n airtight package which is filled with N₂ or a noble gas.

Such a structure keeps oxygen and water out of the package, and prevents the solid electrolyte and the transparent electrode from oxidizing and reducing. This makes it possible to provide a solid-state imaging device implementing a stable operation and high reliability.

In order to solve the above problems, an imaging apparatus according to another aspect of the present invention includes: the solid-state imaging device according to one of the above implementations; and a signal processing device which adjusts an amount of light entering the imaging region, wherein the signal processing device includes: a determining unit which previously determines before exposure whether or not luminance signals provided from the pixel units saturate; and a transmittance control unit which, in the case where the determining units determines that the luminance signals saturate, electrically controls a transmittance of the light attenuation filter so as to prevent the luminance signals in the exposure from saturating, by setting before the exposure a voltage to be applied to the light attenuation filter.

According the aspect, the light attenuation filter controls the amount of transmitting light during the exposure based on a previous determination of saturation with luminance signals. Such a feature allows an imaging apparatus to be downsized and obtain an image even under high lighting intensity.

In the solid-state imaging device according to another aspect of the present invention, the solid-state imaging device may include the light attenuation filter provided for each of pixel blocks which includes pixel units arranged in a two-by-two matrix, the signal processing device may further include a specifying unit which specifies a region at which saturated signals are provided, based on previously-obtained intensity distribution of the luminance signals that are observed in the imaging region, and the transmittance control unit may electrically control the transmittance of the light attenuation filter so as to prevent the luminance signals in the exposure from saturating, by setting before the exposure the voltage to be applied to the light attenuation filter provided for each of the pixel blocks, the luminance signals being observed in a pixel block included in the pixel blocks and the specified region.

Thanks to such features, saturation is determined for each pixel block, and the transmittance of light can be controlled for each pixel block where saturated signals are found. This can provide a solid-state imaging apparatus which implement a wide dynamic range that makes it possible to obtain an object with high brightness and an object with low brightness.

In the solid-state imaging device according to another aspect of the present invention, the solid-state imaging device may include pixel blocks each including pixel units arranged in a two-by-two matrix, the pixel blocks may be arranged in a Bayer pattern, and each of the pixel blocks may include a G1 pixel unit and a G2 pixel unit which obtain a green signal, an R pixel unit which obtains a red signal, and a B pixel unit which obtains a blue signal, the light attenuation filter may be provided only over the G1 pixel unit and the G2 pixel unit, the determining unit may previously determine before the exposure whether or not luminance signals provided from the G1 pixel unit and the G2 pixel unit saturate, and the transmittance control unit may, in the case where the determining units determine that the luminance signals saturate, electrically control the transmittance of the light attenuation filter so as to prevent the luminance signals in the exposure from saturating, by setting before the exposure the voltage to be applied to the light attenuation filter.

Since the above structure makes it possible to provide a light attenuation filter only for a green signal having the highest luminosity factor. Hence the driving area of the light attenuation filter is made small so that driving power can be reduced, as well as an image having high brightness can be captured while maintaining a sensitivity in red and blue having a low luminosity factor. Such features make it possible to implement a solid-state imaging device having a wide dynamic range with low power consumption.

### Advantageous Effects

The solid-state imaging device according to the present invention has a light attenuation filter including an electrochromic element and formed for each of pixel units and for each of pixel blocks. Hence the solid-state imaging device itself can be thinner and further downsized. In the imaging apparatus of the present invention, a signal processing device is provided for adjusting the transmittance of the light attenuation filter based on the determination of saturated signals. Such a feature contributes to controlling the transmittance of light according to the luminance observed in an imaging region. Consequently, this contributes to providing a solid-state imaging apparatus which can implement a wide dynamic range and obtain an image under high lighting intensity.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 depicts a functional block diagram showing a structure of an imaging apparatus according to Embodiment 1 of the present invention.

FIG. 2 depicts a circuit diagram of a pixel block included in the solid-state imaging device according to Embodiment 1 of the present invention.

FIG. 3A depicts a flowchart showing an operation of a signal processing device according to Embodiment 1 of the present invention.

FIG. 3B depicts a graph showing a relationship between a charge storage capacity and a charging time observed in a photoelectric converting unit.

FIG. 4 depicts an exemplary schematic cross-sectional view of a unit pixel included in the solid-state imaging device according to Embodiment 1 of the present invention.

FIG. 5 depicts a cross-sectional view and a drive principle of a light attenuation filter according to Embodiment 1 of the present invention.

FIG. 6 shows a light transmission spectrum of WO₃ before and after the introduction of hydrogen.

FIG. 7 depicts an exemplary cross-sectional view of a solid-state imaging device in a modification according to Embodiment 1 of the present invention.

FIG. 8 shows in cross-section a manufacturing process of a light attenuation filter included in the solid-state imaging device according to Embodiment 1 of the present invention.

FIG. 9 depicts a schematic cross-sectional view showing how the solid-state imaging device according to Embodiment 1 of the present invention is mounted.

FIG. 10 depicts a schematic view showing an, imaging region of a solid-state imaging device according to Embodiment 2 of the present invention.

FIG. 11A depicts a flowchart showing an operation of a signal processing device according to Embodiment 2 of the present invention.

FIG. 11B depicts a graph showing how the photoelectric converting unit of the signal processing device adjusts a charge storage capacity.

FIG. 12 depicts a schematic view showing an imaging region of a solid-state imaging device according to Embodiment 3 of the present invention.

FIG. 13 depicts a cross-sectional view and a drive principle of a light attenuation filter according to Embodiment 4 of the present invention.

FIG. 14 is a cross-sectional view showing a structure of a conventional solid-state imaging device described in Patent Literature 1.

### DESCRIPTION OF EMBODIMENTS

Described hereinafter are embodiments of the present invention with reference to the drawings.

### Embodiment 1

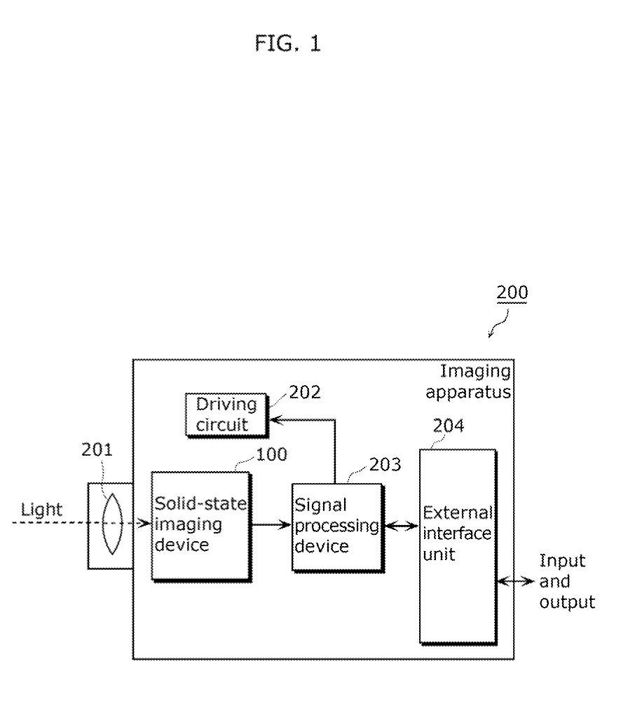

FIG. 1 is a functional block diagram showing a structure of an imaging apparatus according to Embodiment 1 of the present invention. An imaging apparatus 200 in FIG. 1 is a digital camera and includes a solid-state imaging device 100, a lens 201, a driving circuit 202, a signal processing device 203, and an external interface unit 204.

The signal processing device 203 causes the driving circuit 202 to drive the solid-state imaging device 100, receives an output signal from the solid-state imaging device 100, processes the output signal, and provides the processed signal outside via the external interface unit 204.

The solid-state imaging device 100 includes an active light attenuation filter for each of pixel units or pixel blocks, so that the filter attenuates the amount of incident light. The signal processing device 203 previously sets an attenuation rate of the light attenuation filter for each of the pixel units or pixel blocks to adjust the amount of incident light coming to the imaging region.

Such a structure makes it possible to control, based on brightness of the object, the amount of transmitted light which arrives at the imaging region. As a result, en image can be obtained under high lighting intensity. Moreover, for example, the above feature may be implemented for each Bayer pattern, so that an object having low brightness and an object having high brightness can be presented in a same image with excellent gradation. Detailed below are the essential parts of the present invention; namely, the solid-state imaging device 100 and the signal processing device 203.

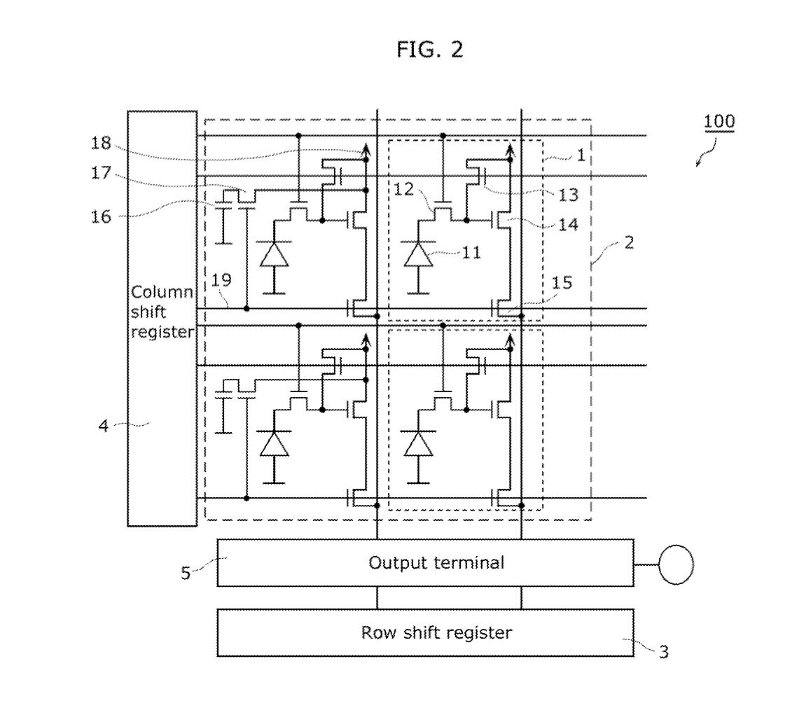

FIG. 2 depicts a circuit diagram of a pixel block included in a solid-state imaging device according to Embodiment 1 of the present invention. The solid-state imaging device 100 in FIG. 2 includes: an imaging region 2 having unit pixels 1 two-dimensionally arranged, a row shift register 3 and a column shift register 4 for selecting a pixel signal, and an output terminal 5 for forwarding outside signals provided from a selected unit pixel 1. Here, each of the unit pixels 1 includes a photoelectric converting unit 11 which is a photo diode.

The imaging region 2 includes multiple unit pixels 1. Each of the unit pixels 1 includes a photoelectric converting unit 11, a transferring transistor 12, a resetting transistor 13, an amplifying transistor 14, and a selecting transistor 15. Each of the transferring transistor 12, the resetting transistor 13, the amplifying transistor 14, and the selecting transistor 15 is a metal-oxide semiconductor (MOS) transistor.

Furthermore, the solid-state imaging dew ice 100 includes a light attenuation filter 16 and a selecting transistor 17. The light attenuation filter 16 is formed on the incident-light-side of the imaging region 2. Moreover, the selecting transistor 17 is provided between a voltage line 18 and the light attenuation filter 16. The gate of the selecting transistor 17 is connected to a read line 19. A control signal from the read line 19 renders the voltage line 18 and the light attenuation filter 16 conductive and non-conductive.

To the voltage line 18, both of the positive electric potential and negative electric potential can be selectively applied. Here, in order to reduce the transmittance of the light attenuation filter 16, for example, a positive voltage is applied to the voltage line 18, and the selecting transistor 17 is rendered conductive. Hence the positive voltage is applied to the light attenuation filter 16. Moreover, a desired transmittance can be obtained for the light attenuation filter 16 by the control for a conduction period of the selecting transistor 17; that is, a period to apply a positive voltage to the light attenuation filter 16. Then the selecting transistor 17 is rendered non-conductive, and the normal imaging drive is carried out at the set transmittance. After the imaging drive ends, a negative voltage is applied to the voltage line 18, the selecting transistor 17 is rendered conductive, and the transmittance of the light attenuation filter 16 is changed to the original one.

The operation for adjusting the transmittance by the light attenuation filter 16, the operation for resetting the photoelectric converting unit 11, and the imaging operation by the unit pixel 1 are carried out in a chronological order. Hence the charges stored in the photoelectric converting unit 11 can be reset before the after-described measurement of the saturation with luminance signals and the imaging operation. Such a feature makes it possible to separately carry out, without providing new signal lines, the operation for adjusting the transmittance of the light attenuation filter 16, the operation for resetting the photoelectric converting unit 11, and the imaging operation by the unit pixel 1.

It is noted that, in Embodiment 1, the selecting transistor 17 is provided for controlling the application of a voltage to the light attenuation filter 16; instead, the voltage line 18 is made pulse-driven in order to eliminate the need for the selecting transistor 17. In the operation for adjusting the transmittance of the light attenuation filter 16, the read line 19 is to be off. Furthermore, when the voltage line 18 is kept 0V during the exposure period, the transmittance set in the adjustment operation cannot change during the exposure period. Moreover, in reading a signal from the photoelectric converting unit 11, a voltage is applied to the voltage line 18. Here, the change in the transmittance of the light attenuation filter 16 will not make the read signal a false one if charges have already been stored. After the reading, the read line 19 may be turned off again, and the light attenuation filter 16 may be turned off. Such a feature eliminates the need for a transistor for controlling the application of a voltage to the light attenuation filter 16, which makes it possible to assign the light attenuation filter 16 to each of pixels even though the pixel is small.

(Principle of Adjusting Transmittance)

Described next is the signal processing device 203 according to Embodiment 1 of the present invention. In order to drive the light attenuation filter 16; namely an active light attenuation filter, of the present invention, it is necessary to previously determine to what degree the light needs to be attenuated. Hence the present invention introduces preliminary capturing immediately before capturing an image of the object in order for the signal processing device 203 to determine the saturation with luminance signals.

The signal processing device 203 includes: a determining unit which previously determines before exposure whether or not luminance signals, provided from a unit pixel 1 or a pixel block including multiple unit pixels 1, saturate; and a transmittance control unit which, in the case where the determining unit determines that the luminance signals saturate, electrically control a transmittance of the light attenuation filter 16 so as to prevent the luminance signals in the exposure from saturating, by setting before the exposure a voltage to be applied to the light attenuation filter 16.

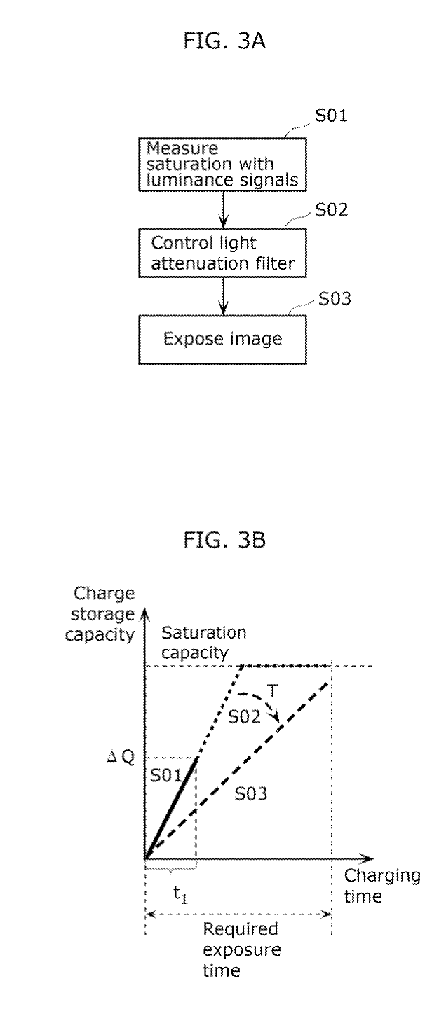

FIG. 3A depicts a flowchart showing an operation of a signal processing device according to Embodiment 1 of the present invention. FIG. 3B depicts a graph showing a relationship between the charge storage capacity and a storing time observed in a photoelectric converting unit.

In Embodiment 1, the signal processing device 203 measures saturation with luminance signals (Step S01), reduces the transmittance of the light attenuation filter 16 (Step S02), and captures an image of the object (Step S03).

First, as the measurement of the saturation with luminance signals, the determination unit in the signal processing device 203 calculates ΔQ/t1 that is the gradient of the graph in FIG. 3B, from a charge storage capacity, that is ΔQ, showing an amount of charges stored by the exposure period for the period of t1. Then, the determination unit determines in a signal processing region whether or not the luminance signals saturates during the exposure period that is required when the light attenuation filter 16 does not attenuate the incident light; that is, whether or not the charge storage capacity reaches a saturation capacity.

The signal processing device 203 previously assigns to the signal processing region a threshold value for luminance signal intensity. Then, in the case where the luminance signals exceed the above threshold value, the transmittance control unit activates the light attenuation filter 16 to reduce ΔQ/t1; that is storage efficiency, by a transmittance T so as to prevent the saturation.

The above features make it possible to determine whether or not the photoelectric converting unit 11 is under saturation lighting intensity and saturation brightness when obtaining an image under high lighting intensity and capturing an object having high brightness, and to control a light transmittance of the light attenuation filter 16 in order to prevent saturation of the photoelectric converting unit 11. Consequently, an image is successfully obtained under the high lighting intensity.

According to Embodiment 1 of the present invention, the light attenuation filter 16 controls the amount of transmitting light in the exposure based on the determination of saturation with luminance signals that is carried out in the preliminary capturing. Such a feature allows the imaging apparatus 200 to be downsized and obtain an image even under high lighting intensity.

Described next are a structure of the light attenuation filter and how the light attenuation filter works.

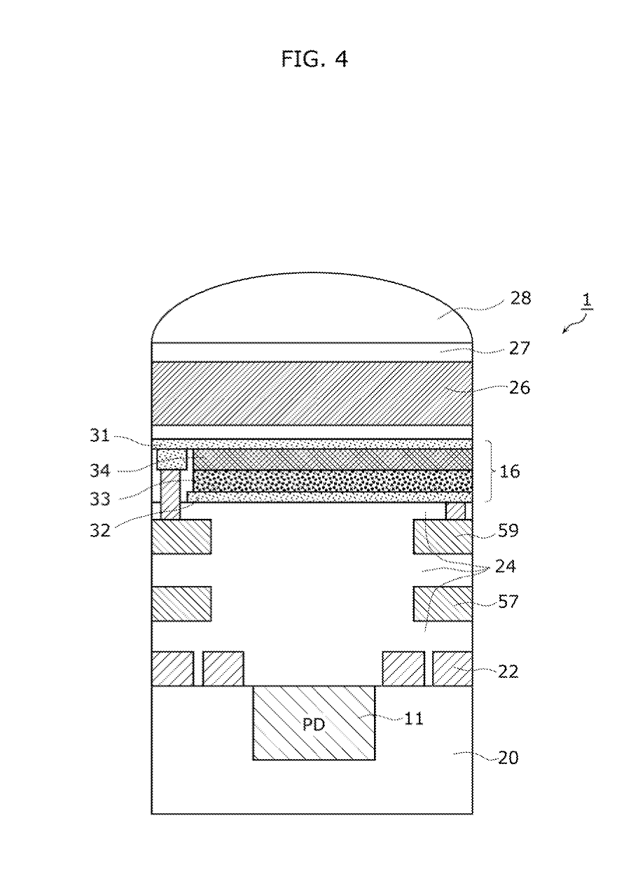

FIG. 4 depicts an exemplary schematic cross-sectional view of a unit pixel included in the solid-state imaging device according to Embodiment 1 of the present invention. The unit pixel 1 in FIG. 4 includes the photoelectric converting unit 11, the light attenuation filter 16, a semiconductor substrate 20, a gate and a gate wire 22, an interlayer film 24, a color filter 26, a planarizing film 27, a microlens 28, and wiring layers 57 and 59.

The light attenuation filter 16 is provided above the topmost wiring layer 59 and below the color filter 26. The wiring layers 57 and 59 are made of, for example, AlCu. Moreover, there are two wiring layers; namely the wiring layers 57 and 59.

The light attenuation filter 16 includes transparent electrodes 31 and 32, an active-material layer 33, and a solid electrolyte layer 34. The light attenuation filter 16 is formed in a capacitor structure of a laminated film, including the active-material layer 33 and the solid electrolyte layer 34, sandwiched between the transparent electrodes 31 and 32. The transparent electrodes 31 and 32 are an upper transparent electrode and a lower transparent electrode, respectively. Each of the transparent electrodes 31 and 32 is electrically connected to the wiring layer 59. Through the wiring layer 59, the transparent electrodes 31 and 32 are electrically connected to the selecting transistor 17 (not shown) formed on the semiconductor substrate 20. As described above, rendering the selecting transistor 17 conductive and non-conductive controls a voltage to be applied to the light attenuation filter 16.

Described next is how the light attenuation filter 16 works.

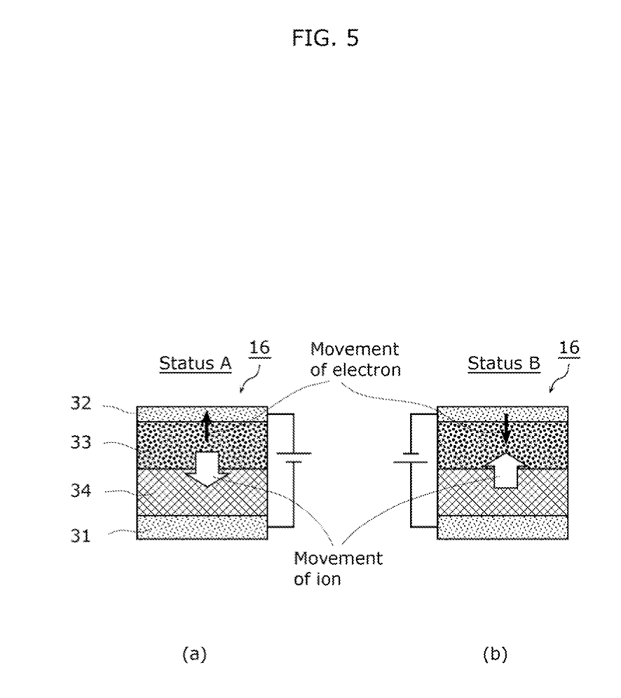

FIG. 5 depicts a cross-sectional view and a drive principle of the light attenuation filter according to Embodiment 1 of the present invention. The light attenuation filter 16 in Embodiment 1 uses an electrochromic element.

The electrochromic element is a collective term of an element whose absorbing spectrum of the material changes by application of a voltage, followed by the change in the color of the element itself. For example, the liquid crystal is also a kind of the electrochromic element since the transmittance of the liquid crystal changes when an electric field changes the orientation of the liquid crystal molecules. In particular, there is an electrochromic element including solid electrolyte which changes an absorbing spectrum by an oxidation-reduction reaction caused by ion movement in a solid substance. Such an electrochromic element is widely used as a display element since the element has no polarization dependency as found in the liquid crystal, and includes a material showing a peculiar spectrum.

The status A in the illustration (a) in FIG. 5 shows that a positive voltage is applied to the transparent electrode 32 on the top face of active-material layer 33, so that the active material of the active-material layer 33 comes to an oxidation state. Hence, as soon as ions move from the active-material layer 33 to the solid electrolyte layer 34, electrons are released from the active-material layer 33 to the transparent electrode 32. In the status A, the light attenuation filter 16 becomes transparent.

In contrast, the status B in the illustration (b) in FIG. 5 shows a reduction state; that is, a negative voltage is applied to the transparent electrode 32 on the top face of active-material layer 33, so that positive ions in the solid electrolyte layer 34 are attracted to the active-material layer 33 as well as electrons are injected from the transparent electrode 32 to the active-material layer 33.

The only difference between the status A and the status B is that their polarities are reversed. Thus the voltage may be applied to any one of the negative only, the positive only, both of the positive and the negative. It is noted that conduction ions are basically positive ions. Thus the positive ions move in a direction opposite to the direction of the electrons. In the electrochromic element, a current which flows in and out thereof is equivalent to a redox current that corresponds to the moving distance of the ions from the active material. Hence, the time to apply a voltage to an electrode can be used to control the moving distance of the ions. Consequently, such control makes it possible to control the amount of transmitted light, and implement a solid-state imaging apparatus that successfully captures an image under high lighting intensity.

Described next are the materials that the light attenuation filter 16 is made of. The active-material layer 33 included in the light attenuation filter 16 is made of one of oxides-amorphors WO₃, amorphors MoO₃, and amorphors IrO₂. Furthermore, the solid electrolyte layer 34 is made of at least one of the oxides —ZrO₂, Ta₂O₅, Cr₂O₃, V₂O₅, SiO₂, Nb₂O₅, and HfO₂.

Exemplified here is the case where WO₃ is used as the material for the active-material layer 33, and Ta₂O₅ is used as a material for the solid electrolyte layer 34. The combination of WO₃ and Ta₂O₅ is typical a typical one for an electrochromic element. The application of a voltage to the transparent electrodes 31 and 32 causes an oxidation-reduction reaction along with movement of ions between WO₃ and Ta₂O₅, followed by a significant change in the electron structure of the WO₃. This makes it possible to gradually change the light attenuation filter 16 between a transparent state and a colored state.

Here, the principle of coloring the active-material layer 33 is described, using WO₃ as an example. WO₃ is a strongly-ionizable oxide. W of WO₃ is similar to the state of W⁶⁺ whose valence electron is taken by O. In such a state, WO₃ is a transparent material whose bandgap is approximately 3.8 eV When hydrogen and alkali metal exist here, the hydrogen and the alkali metal enter between W and O to cause a reduction reaction so that the electrons in the hydrogen and the alkali metal move to W. The reduced electrons occupy the d electron level of W, and significantly contribute to absorption of light.

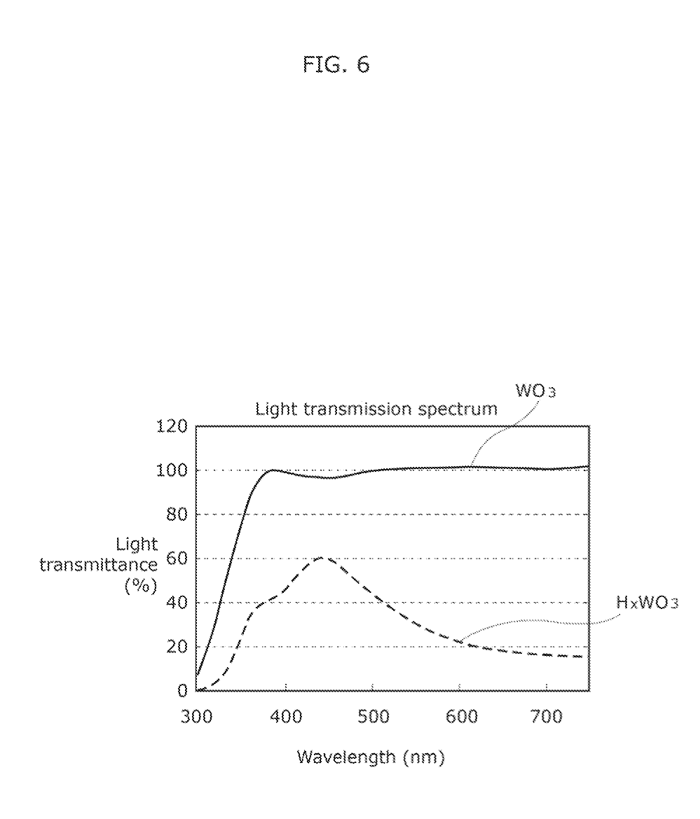

FIG. 6 shows a light transmission spectrum of WO₃ before and after the introduction of hydrogen. In HₓWO₃, the hydrogen is non-stoichiometrically introduced to WO₃. As shown in FIG. 6, the visible light region has a significantly high degree of transparency when no hydrogen is found (WO₃). In contrast, in HₓWO₃ with the hydrogen introduced, a great degree of light absorption is observed from green to red. In the blue region which shows relatively small degree of light absorption, the transmittance decreases by as low as 40%. Since blue is low in luminosity, HₓWO₃ including the hydrogen is sufficient enough even in the blue region to work as a light attenuation filter for visible light.

Preferably, the active-material layer 33 is an amorphous film. When WO₃ is crystallized, there are fewer sites for ions such as hydrogen to settle at, and the moving speed of the ions become slower. When WO₃ is amorphous, however, there are many sites for the ions to settle at, and the moving speed of the ions are faster than those in the crystallized WO₃. Hence, the amorphous film is most suitable to the present invention. Furthermore, since the amorphous WO₃ can be deposited at a low temperature, the affinity of the amorphous WO₃ with silicon processing is very high.

Furthermore, in MoO₃ which is an oxide of Mo that is homologous with W and in IrO₂ which is an oxide of a strongly-ionizable Ir, the electrochromic phenomenon occurs between a transparent state and a colored state according to a principle similar to the above one. In other words, WO₃, MoO₃, and IrO₂ are excellent since they are transparent oxide materials whose light transmittance changes by the movement of the ions, great in responsiveness and easy to produce.

Next, the solid electrolyte layer 34 is described. In Embodiment 1, H⁺ ions are used as conduction ions. Since the H⁺ ions move between the solid electrolyte layer 34 and the active-material layer 33, the required material for the electrolyte layer 34 should be a transparent one since such a material makes it easy for the H⁺ ions to be stored and to move. Moreover, the conduction ions are driven by an electric field found in the solid electrolyte layer 34 and the active-material layer 33. Hence the solid electrolyte layer 34 should be insulating. ZrO₂, Ta₂O₅, Cr₂O₃, V₂O₅, SiO₂, Nb₂O₅, and HfO₂ are transparent oxide dielectrics providing excellent electrical insulation. They are materials including H⁺ ions and capable of supplying ions to an active material. The radius of an H⁺ ion is the shortest of all the ions, which makes the diffusion rate of the H⁺ ion high, and contributes to high-speed switching of the light attenuation filter 16. Hence Embodiment 1 demonstrates the best mode in conduction of H⁺ ions.

(Manufacturing Technique)

Described here is an exemplary technique for manufacturing a solid-state imaging device including the light attenuation filter 16 made of WO₃ and Ta₂O₅.

In the electrochromic element, a device structure according to Embodiment 1 of the present invention includes an electrochromic element which is made of a pair of the active-material layer 33 and the solid electrolyte layer 34, and provided across the interlayer film 24 from the topmost wiring layer 59. Such a structure requires the light attenuation filter 16 to be formed before a color filter. Hereinafter detailed is a manufacturing process after the topmost wiring layer 59.

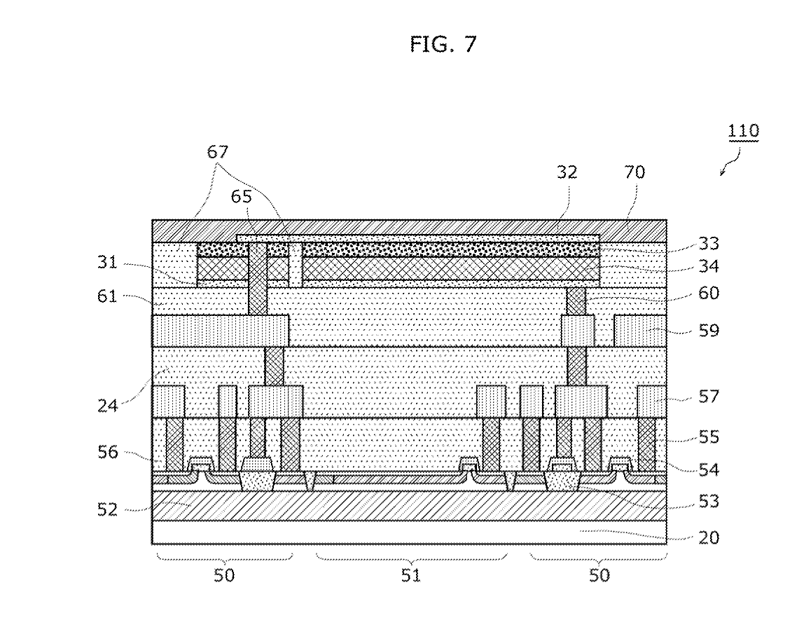

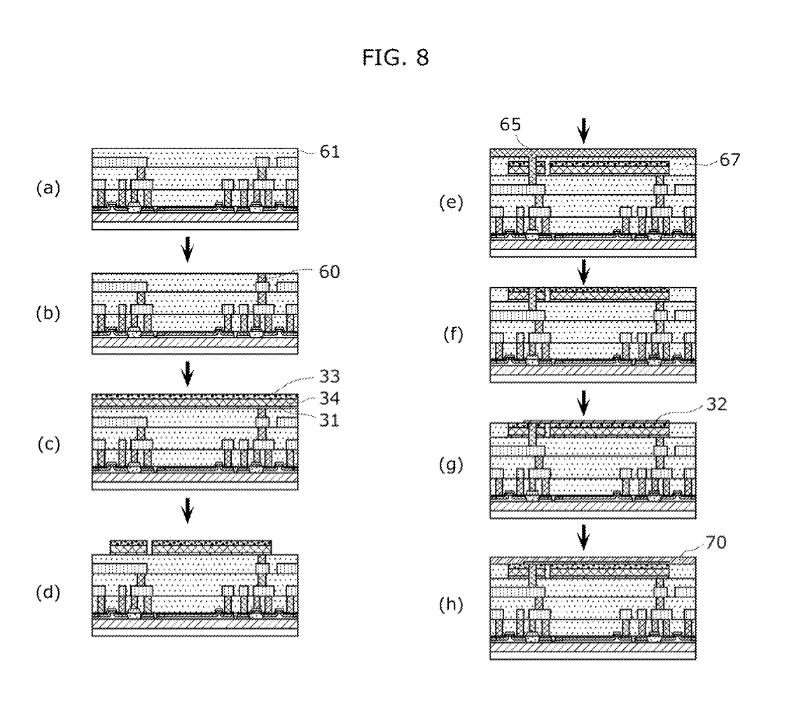

FIG. 7 depicts an exemplary cross-sectional view of a solid-state imaging device in a modification according to Embodiment 1 of the present invention. A solid-state imaging device 110 in FIG. 7 is a MOS image sensor. FIG. 8 shows in cross-section a manufacturing process of the light attenuation filter included in the solid-state imaging device according to Embodiment 1 of the present invention.

As shown in FIG. 7, a diffusion region 52 is formed on the semiconductor substrate 20 by ion implantation. An imaging region 51 and a peripheral circuit region 50 of the pixel unit are formed over the semiconductor substrate 20.

A transistor 54 is electrically separated by an element separating portion 53. After the transistor 54 is formed, an interlayer film 56, including an insulator such as boron phosphor silicate glass (BPSG), is formed. The interlayer film 56 is planarized by chemical mechanical polishing (CMP) and etchback. Then a contact hole is formed by dry etching and a metal plug 55 is formed by the metal CVD. With the metal plug 55 exposed, aluminum is deposited by sputtering and patterned by dry etching to form a wiring layer 57. Repeating the above process, multi-layered wiring is formed. The transistor 54 is, for example, any one of the transferring transistor 12, the resetting transistor 13, the amplifying transistor 14, and the selecting transistors 15 and 17 in FIG. 2.

The solid-state imaging device 110 according to Embodiment 1 employs two-layer wiring. Hence, over the wiring layer 57 that is the first layer, the interlayer film 24 made of a dielectric is formed and planarized. Then a metal plug is formed and a second layer that is a wiring layer 59 is formed.

Described next is a process of forming the light attenuation filter 16. As shown it the illustration (a) in FIG. 8, an interlayer film 61 made of a dielectric is formed by the BPSG and planarized by the CMP.

Then, as shown in the illustration (b) in FIG. 8, a metal plug 60 is formed. Here, the metal plug 60 is left exposed.

Next, as shown in the illustration (c) in FIG. 8, the transparent electrode 31, the solid electrolyte layer 34, and the active-material layer 33 of the light attenuation filter 16 are laminated and deposited. Here the transparent electrode 31 provided below is electrically connected to the metal plug 60. Basically, the light attenuation filter 16 needs to be light transmissive. Thus the transparent electrode 31 is made of indium tin oxide (ITO) which is transparent to visible light. The transparent electrode 31 is, for example, 200 nm in film thickness. It is noted that, in Embodiment 1, the light attenuation filter 16 is provided above the two layers; namely the wiring layers 57 and 59. However, the pixel structure shall not be defined as it is; instead, the light attenuation filter 16 may be provided between the wiring layer 57 that is the first layer and the wiring layer 59 that is the second layer.

Then, as shown in the illustration (d) in FIG. 8, the light attenuation filter 16 is patterned by dry etching for element isolation.

Next, as shown in the illustration (e) in FIG. 8, an interlayer film 67 is deposited. The interlayer film 67 has insulation properties and includes borophosphosilicate glass (BSPG) and fluorine doped silica glass (FSG). Then the interlayer film 67 is planarized by the CMP. Then, oxide-film dry etching is applied to form a via hole for a metal plug. After that, metal including a metal plug 65 is deposited by the metal chemical vapor deposition (CVD).

Next, as shown in the illustration (f) in FIG. 8, the deposited metal is polished by the CMP until WO₃ in the active-material layer 33 is exposed.

Then, as shown in the illustration (g) in FIG. 8, the transparent electrode 32 is formed and patterned. Here the transparent electrode 65 and the transparent electrode 32 are electrically connected to each other. Basically, the light attenuation filter 16 needs to be light transmissive. Thus the transparent electrode 31 is made of ITO which is transparent to visible light.

Finally, as shown in the illustration (h) in FIG. 8, a planarizing film 70 is formed. Then, a not-shown color filter and a micro lens are formed. That is how the solid-state imaging device 110 of the present invention is formed.

Following laminating and forming of the unit pixel 1, the above process provides the light attenuation filter 16 capable of adjusting the transmittance for each pixel. Consequently, an exposure requirement can be set for each pixel block including one or more unit pixels 1. Hence when both an object having high brightness and an object having low brightness are included in a single angle of view, the amount of transmitting light can be controlled for each pixel unit or each pixel block. Such a feature contributes to implementing a wide dynamic range which successfully expresses clear contrast of the object having low brightness, and keeps a pixel region having high luminance from being saturated.

Furthermore, the light attenuation filter 16 is formed, along with the pixel, above the photoelectric converting unit 11 via the interlayer films 24 and 61 made of a dielectric. Compared with the structure in which a light attenuation filter is formed separately from a pixel and provided on the pixel, the above structure makes it possible to reduce ghost and lens flare caused by multiple reflections of light.

Hereinafter detailed is how the transparent electrodes 31 and 32, the solid electrolyte layer 34, and the active-material layer 33 are formed.

ITO electrodes, such as the transparent electrodes 31 and 32, are deposited by, for example, the pulse laser deposition (PLD). In the PLD, a pulse laser is converged and emitted to a desired material. The temperature of the surface of the material rises instantaneously and locally. Thus the atoms of the material evaporate, and the evaporated atoms of the material are re-deposited on a substrate in another place. The target for the atom vaporization with the laser is an oxide, and a deposition atmosphere is oxygen. This contributes to depositing an oxide having high homogeneity. Specifically, for example, the ITO target receives a KrF laser whose wavelength is 248 nm; that is an excimer laser, and is deposited on wiring. Preferably, the depositing temperature is 300 C.° since the temperature is low enough to keep the aluminum-made wiring layers 57 and 59 from melting.

It is noted that the PLD is used in Embodiment 1; instead, the reactive sputtering and the heating evaporation may be used. Excessively thin transparent electrodes 31 and 32 inevitably increase their resistance. Preferably, the electrodes are thicker than or equal to 50 nm. In contrast, excessively thick transparent electrodes 31 and 32 inevitably increase the distance between the micro lens 28 and the photoelectric converting unit 11 longer than the focal length of the micro lens. Such a long distance decreases the concentration of light. In Embodiment 1, the ITO is 200 nm thick. Preferably, the film thickness is as thin as possible.

On the top of the transparent electrode 31, the solid electrolyte layer 34 and the active-material layer 33 are stacked. In Embodiment 1, the active-material layer 33 and the solid electrolyte layer 34 are made of WO₃ and Ta₂O₅; respectively. The active-material layer 33 is 300 nm thick and the solid electrolyte layer 34 is 200 nm thick.

In Embodiment 1, the WO₃ film and Ta₂O₅ film are also deposited by the PLD.

On the transparent electrode 31 made of ITO, Ta₂O₅ is deposited in an oxide atmosphere at the depositing temperature of 400 C.°. This is because deposition at a temperature of approximately higher than 400 C.° can melt the aluminum-made wiring layer. In depositing the oxide at a low temperature, however, the oxidation does not progress sufficiently, and the lack of oxygen makes the Ta₂O₅ low in density and includes much oxygen deficiency. This inevitably leads to a decrease in insulation properties and transmittance. Thus, from this stand point, the Ta₂O₅ is preferably deposited at as high temperature as possible; that is approximately 400 C.°.

After the Ta₂O₅ is deposited, the hydrogen annealing is provided to the Ta₂O₅ at approximately 400 C.° for about one minute in order to introduce hydrogen into the Ta₂O₅. Excessively long hydrogen annealing inevitably leads to the reduction of the Ta₂O₅. This reduction not only increases the amount of leak current and decreases transparency but also causes a decrease in the conductivity of the ITO transparent electrode. Thus, in order to perform low-concentration hydrogen doping into the topmost Ta₂O₅ film so that excessive hydrogen is not introduced, the time and flow of the hydrogen annealing need to be controlled. It is noted that, in the hydrogen annealing, a temperature of approximately 400 C.° is required in order for WO₃ to incorporate hydrogen atoms. Hence the solid electrolyte layer 34 is formed.

Next, again using the PLD, at the depositing temperature of 200 C.°, WO₃ is formed on the Ta₂O₅. In order to keep the hydrogen from being eliminated from the hydrogen-introduced Ta₂O₅, the WO₃ is preferably formed at a temperature of 300 C.° or lower. In Embodiment 1, the WO₃ is deposited at approximately 200 C.°. As described before, the active-material layer 33 of the present invention may preferably be an amorphous film. When WO₃ is crystallized, there are fewer sites for ions such as hydrogen to settle at, and the moving speed of the ions become slower. When WO₃ is amorphous, however, there are many sites for the ions to settle at, and the moving speed of the ions are faster than those in the crystallized WO₃. Hence, the amorphous film is most suitable to the present invention. Furthermore, since the amorphous WO₃ can be deposited at a low temperature, the affinity of the amorphous WO₃ with silicon processing is very high. Hence the active-material layer 33 is formed.

The structure of the above-described light attenuation filter 16 makes it possible to produce a thinner light attenuation filter. Consequently the thinner film contributes to implementing a small solid-state imaging device which can obtain finer images.

Moreover, in Embodiment 1, the active-material layer 33 and the solid electrolyte layer 34 are respectively made of WO₃ and Ta₂O₅, However, the materials shall not be defined as they are. Any material can be used as far as a transmission spectrum changes by ion movement. MoO₃ and IrO₂ may be used for the active-material layer 33. Such a feature makes it possible to form MoO₃ and IrO₂ in a thin film whose color can be converted between transparent and deep blue, which contributes to implementing a small solid-state imaging device having a wide dynamic range.

Moreover, the solid electrolyte layer 34 may be a transparent insulator which includes hydrogen and is capable of ion conduction. The solid electrolyte layer 34 may be made of ZrO₂, Ta₂O₅, Cr₂O₃, V₂O₅, SiO₂, Nb₂O₅, and HfO₂. In particular, ZrO₂, Cr₂O₃, and V₂O₅ are effective materials since they have excellent ion conduction. Since those materials use hydrogen as a medium for ion conduction, ions are easily introduced into solid electrolyte. Besides, the radius of a Hydrogen ion is small. Such features contribute to high-speed switching of the transmittance of the light attenuation filter 16. Consequently, a high-speed solid-state imaging device can be implemented at a low cost.

It is noted that, in Embodiment 1, the active-material layer 33 is stacked on the solid electrolyte layer 34; instead, the solid electrolyte layer 34 may be stacked on the active-material layer 33. Moreover, in Embodiment 1, the active-material layer 33 is approximately 200 nm thick and the solid electrolyte layer 34 is approximately 300 nm thick. Each thickness is a significantly important parameter in terms of transmittance of light, driving speed, and repeatability. If the active-material layer 33 and the solid electrolyte layer 34 are excessively thin, the layers will transmit light even though they are colored, and cannot fully attenuate the light.

In contrast, if the active-material layer 33 and the solid electrolyte layer 34 are excessively thick, the entire layer structure of the device will be thick. Consequently, the overall film thickness becomes greater than the focal length of a micro lens, and the conversion of the light to the photoelectric converting unit 11 decreases. Furthermore ions, such as hydrogen, enter deep into an active material. Hence it takes much time to get the ions released by an inverse voltage and to transparentize the active material. This makes an operation speed slower. Moreover, the repetition of the operation gradually causes hydrogen to remain in the active-material layer 33, resulting in a gradual loss of the repeatability of transmissivity modulation. Hence, in terms of operation speed, repeatability, and transmittance, it is important to efficiently exchange conduction ions, such as highly-concentrated hydrogen, between the active-material layer 33 and the solid electrolyte layer 34 near the interface between the layers.

In Embodiment 1, both the active-material layer 33 and the solid electrolyte layer 34 are made of an amorphous material. This increases the number of sites at which the conduction ions settles, and active-material layer 33 and the solid electrolyte layer 34 can include highly-concentrated conduction ions. In addition, the active-material layer 33 is formed 200 nm in film thickness to secure the reproducibility of a repetitive operation. It is noted that if the active-material layer 33 is thinner than approximately 100 nm, the transmittance thereof is higher than or equal to 80% even though the layer is colored. Thus, with the excessively thin active-material layer 33, the light attenuation filter 16 does not work sufficiently enough as a light attenuation filter. If the active-material layer 33 is thicker than 1000 nm, hydrogen remains in the active-material layer 33 when ions are conducted from the active-material layer 33 to the solid electrolyte layer 34. Thus it is difficult to secure the transparency of the active-material layer 33. Preferably, the film thickness of the active-material layer 33 may between 100 nm and 100 nm inclusive.

Furthermore, the solid electrolyte layer 34 needs to be thick enough so that the solid electrolyte layer 34 can contain enough hydrogen to be attracted to the active-material layer 33 and has enough volume to be able to efficiently take hydrogen from the active-material layer 33. Hence, preferably, the solid electrolyte layer 34 is thicker than the active-material layer 33.

(Mounting the Solid-State Imaging Device)

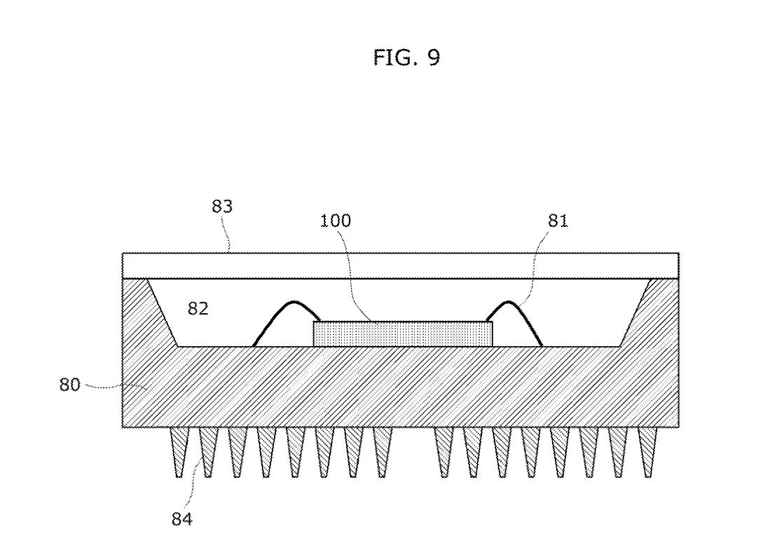

FIG. 9 depicts a schematic cross-sectional view showing how the solid-state imaging device according to Embodiment 1 of the present invention is mounted.

Described below is a process of mounting the solid-state imaging device, with reference to FIG. 9.

First the solid-state imaging device 100 of the present invention is joined to a base 80 having a connecting pin 84 and made of ceramic. Then a metal wire 81 is joined. After that, a gas 82 is encapsulated, and a transparent glass plate 83 seals the gas 82.

Here the gas 82 is a noble gas or N₂. A suitable noble gas is Ar since it is least expensive. The solid electrolyte layer 34, the active-material layer 33, and the transparent electrodes 31 and 32 are all made of oxides. From the viewpoint of reliability, the layers and the electrodes are preferably separated from a supply source of hydrogen as far as possible since excessive hydrogen causes a reduction reaction. Even though a protection film is provided in the device structure, hydrogen atoms supplied from moisture included in the atmosphere gradually reduce the oxides, and deteriorate the characteristics of the electrochromic element. Hence when a noble gas such as Ar and an inactive gas such as N₂ are used for sealing, the supply of hydrogen is stopped, a stable operation of the device is implemented, and a high reliability is ensured.

It is noted that, preferably, the solid-state imaging device 100 included in the imaging apparatus 200 in FIG. 1 is embedded in the imaging apparatus 200 in the above mounting state.

### Embodiment 2

Embodiment 2 describes a solid-state imaging device whose unit pixels 1 are arranged in the Bayer pattern.

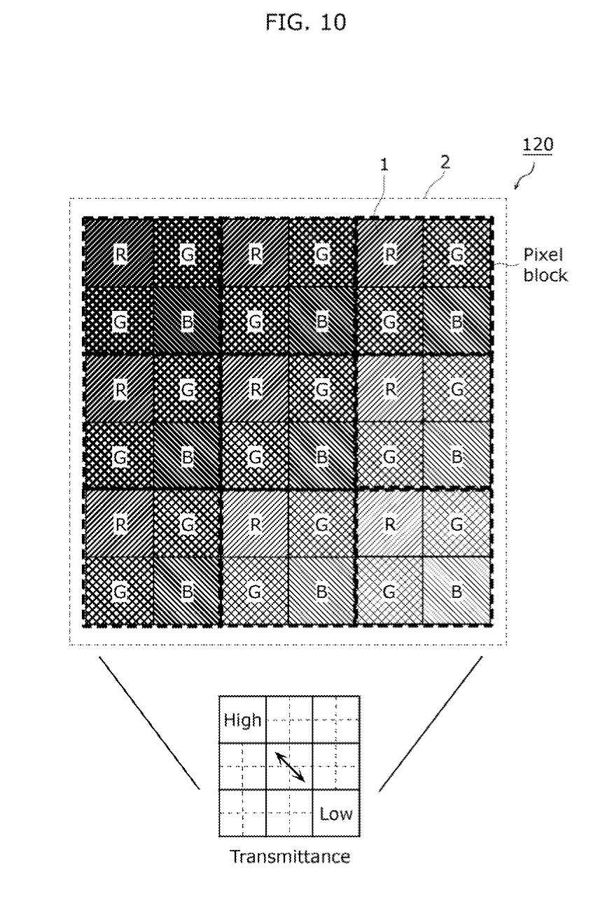

FIG. 10 depicts a schematic view showing an imaging region of the solid-state imaging device according to Embodiment 2 of the present invention. A solid-state imaging device 120 in FIG. 10 differs from the solid-state imaging devices 100 and 110 in Embodiment 1 only on the point that the light attenuation filter 16 is provided for each pixel block including multiple unit pixels 1 arranged in a two-by-two matrix. Hereinafter, the same points between the solid-state imaging device 120 and the solid-state imaging devices 100 and 110 shall be omitted, Only the differences between the solid-state imaging device 120 and the solid-state imaging devices 100 and 110 shall be described.

The unit pixels 1 in an imaging region 2 shown in FIG. 10 are arranged in the Bayer pattern. For each pixel block, which is single unit for the Bayer pattern, an independent light attenuation filter 16 is provided. The light attenuation filter 16 is driven for each Bayer pattern.

In FIG. 10, the transmittance of the light attenuation filter 16 in the uppermost left is set at 100%. The attenuation rate of the light attenuation filter 16 is set higher as the pixel block is located closer to the lowermost right. Suppose an object with high brightness and an object with low brightness are captured at the same time within the same angle of view. Here, for example, the exposure period is to be set so that the object with low brightness can express gradation of contrast. As a result, high-luminance pixels are inevitably saturated. In such a case, however, it is desirable that the exposure period is set so that the gradation of the object with low brightness and the object with high brightness is successfully expressed.

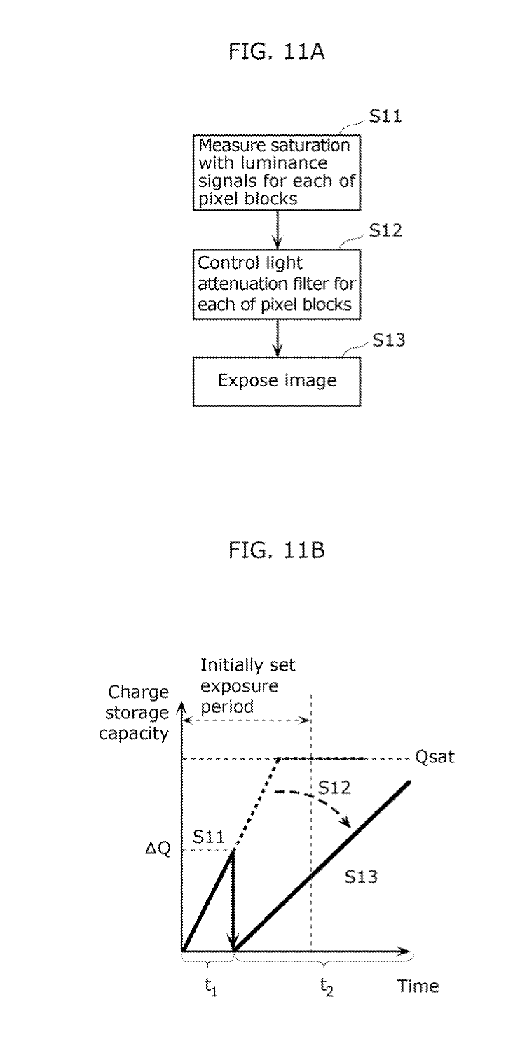

FIG. 11A depicts a flowchart showing an operation of a signal processing device according to Embodiment 2 of the present invention. FIG. 11B depicts a graph showing how the photoelectric converting unit of the signal processing device adjusts a charge storage capacity. In driving the light attenuation filter 16 according to Embodiment 2, the exposure (Step S13) in FIG. 11A involves setting an exposure period so that stored charges do not saturate and gradation of an object with low brightness can be expressed.

The signal processing device according to Embodiment 2 includes: a specifying unit which specifies a region at which saturated signals are provided, based on intensity distribution of the luminance signals that is previously obtained by preliminary capturing and observed in an imaging region; and a transmittance control unit which electrically control the transmittance of the light attenuation filter 16 so as to prevent the luminance signals in the exposure from saturating, by setting before the exposure the voltage to be applied to the light attenuation filter 16 provided for each of the pixel blocks, the luminance signals being observed in a pixel block included in the pixel blocks and the specified region. Here the luminance signals are found in a pixel block included in the region specified by the specifying unit.

Specifically, first, the specifying unit measures saturation with luminance signals for each of pixel blocks during an exposure period t1 (Step S11).

Next, based on the storage efficiency ΔQ/t1 measured in Step S11, the transmittance control unit sets an attenuation rate at T (%) for each pixel block (Step S12) so that output from the pixels in the same pixel block satisfies the following:

(T/100)×(ΔQ/t1)×t2<Qₛₐₜ (Expression 1)

It is noted that Qₛₐₜ is saturation capacity.

Finally, based on the attenuation rate T set for each pixel block in Step 12, the signal processing device causes all the pixel blocks to execute exposure (Step S13).

As described above, for each block, the light attenuation filter 16 is provided, the saturation determination is executed, and the exposure requirement is set. Such features contribute to showing clear contrast of the object having low brightness and implementing a wide dynamic range for a pixel region having high luminance so that the pixel region is kept from being saturated.

### Embodiment 3

Embodiment 3 describes a solid-state imaging device whose pixel blocks are arranged in the Bayer pattern. Here each of the pixel blocks includes G1 and G2 pixels for obtaining a green signal, an R pixel for obtaining a red signal, and a B pixel for obtaining a blue signal, and light attenuation filters are provided only to the G1 and G2 pixels.

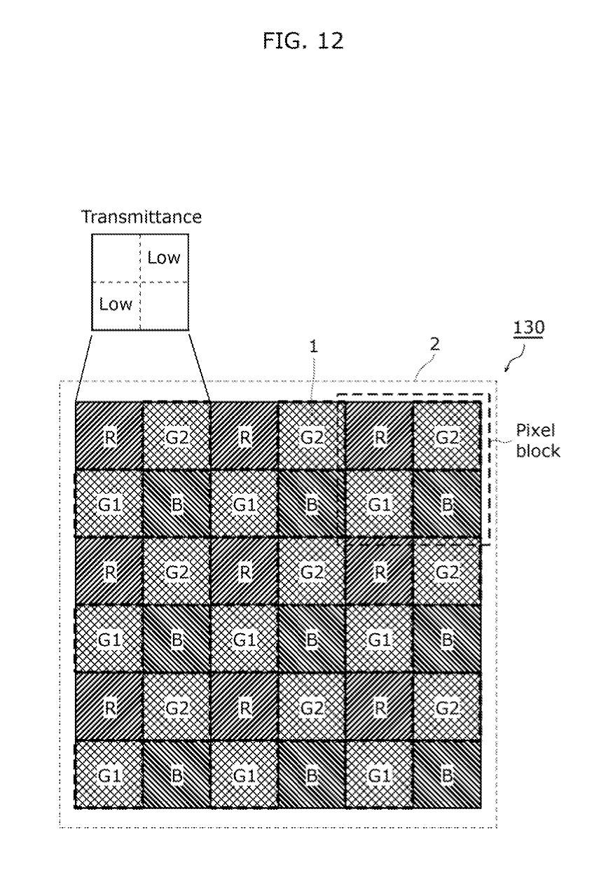

FIG. 12 depicts a schematic view showing an imaging region of the solid-state imaging device according to Embodiment 3 of the present invention. A solid-state imaging device 130 in FIG. 12 differs from the solid-state imaging devices 120 in Embodiment 2 only on the point that the light attenuation filters 16 are provided only over the G1 and G2 pixels included in each pixel block having multiple unit pixels 1 arranged in a two-by-two matrix. Hereinafter, the same points between the solid-state imaging device 130 and the solid-state imaging device 120 shall be omitted. Only the differences between the solid-state imaging device 130 and the solid-state imaging device 120 shall be described.

The unit pixels 1 in an imaging region 2 shown in FIG. 12 are arranged in the Bayer pattern. Among the pixel blocks each of which is a single unit for the Bayer pattern, the light attenuation filters 16 are provided above only the G1 and G2 pixels that have the highest luminosity factor.

Before the exposure, the determining unit included in the signal processing device previously determines whether or not the luminance signals provided from the G1 and G2 pixels saturate. In the case where the determining unit indicates the saturation with the luminance signals, the transmittance control unit electrically controls the transmittance of the light attenuation filter 16 so as to prevent the luminance signals in the exposure from saturating, by setting before the exposure the voltage to be applied to the light attenuation filter 16.

In the Bayer pattern, a G signal contributes most to a luminance signal Y. In order to prevent the luminance signals from saturating, adjusting the light amount of G pixels is effective. Such a feature makes it possible to implement a wide dynamic range without decreasing the S/N of B signals and R signals neither of which are available much. Furthermore, only the areas for the green pixels are used as the driving areas for the electrochromic, and the driving power is successfully reduced. Such a feature makes it possible to implement a wide dynamic range with low power consumption.

### Embodiment 4

Embodiment 4 describes a solid-state imaging device including an insulating layer provided between a solid electrolyte layer and an active material layer.

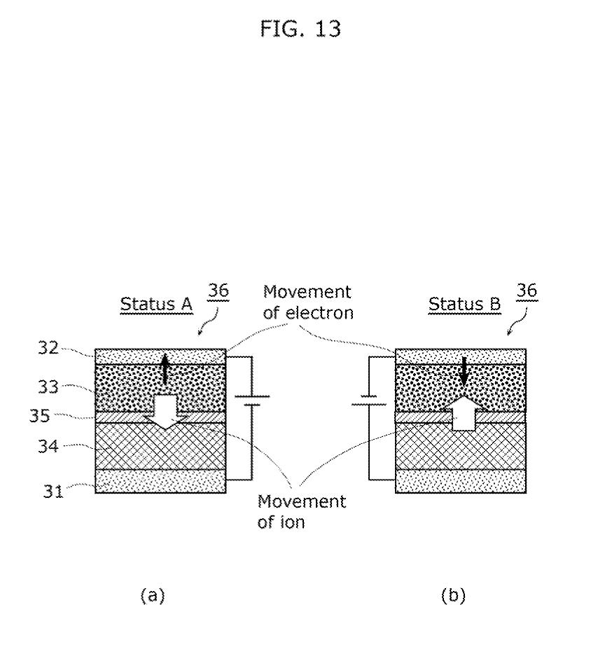

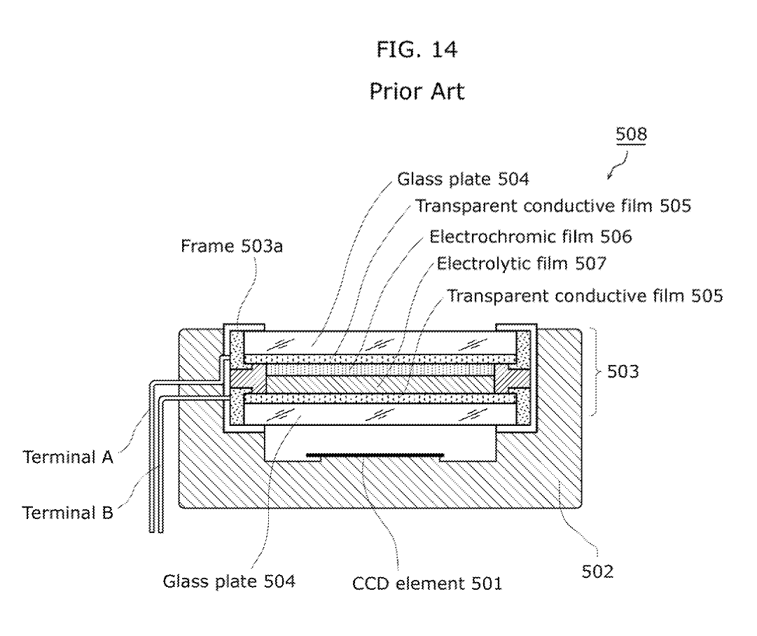

FIG. 13 depicts a cross-sectional view and a drive principle of a light attenuation filter 36 according to Embodiment 4 of the present invention. The light attenuation filter 36 in FIG. 13 differs from the light attenuation filter 16 in FIG. 15 according to Embodiment 1 only on the point that the insulating layer 35 is provided between the solid electrolyte layer 34 and the active-material layer 33. Hereinafter, the same points between the light attenuation filter 36 and the light attenuation filter 16 shall be omitted. Only the differences therebetween shall be described.

As described before, the light attenuation filter 36 is an electrochromic element made of solid electrolyte. Thus, basically, the light attenuation filter 36 needs to include a pair of transparent electrodes, solid electrolyte which is an insulator, and an active material to cause an oxidation-reduction reaction. Furthermore, the movement of electrons in the active-material layer 33 is caused by the movement of ions. Hence the solid electrolyte layer 34 needs to be an insulator. This is because the electron structure of the active-material layer 33 changes by the reduction reaction, and the active-material layer 33 becomes conductive. Hence if there is a leak current in the solid electrolyte layer 34, the solid electrolyte layer 34 will merely be a resistance even though the solid electrolyte layer 34 is formed in a capacitor structure, and will not cause an oxidation-reduction reaction.

However, for materials for a typical solid electrolyte layer 34, such as transition metal oxide including Ta₂O₅ and V₂O₅, oxygen loss is highly likely the cause of leakage. As the area of an element becomes larger, there is more loss of power by the leakage. Consequently, there is not enough ion movement. Moreover, the solid electrolyte layer 34 has a reliability problem in that Joule heat caused by the leakage further increases the oxygen loss, which causes further leakage. Thus, in order to secure the insulation properties of the capacitor structure, a thin insulating layer which has insulation properties and transmits only ions is preferably provided between the solid electrolyte layer 34 and the active-material layer 33.

A preferable material for the insulating layer 35; that is the thin insulating layer, may be one of SiO₂, SiON, and SiN. When SiO₂ is used as the material for the insulating layer 35, exemplary film thickness of the insulating layer 35 may be approximately 5 nm. Furthermore, the chemical vapor deposition (CVD) may be used for depositing the insulating layer 35; instead, the reactive sputtering and the PLD may be used. SiO₂ shows excellent insulation properties, and is suitable for the ion movement of hydrogen and Li. In contrast, an excessive SiO₂ film causes a voltage drop, and a sufficient voltage cannot be applied to the active-material layer 33. Preferably the SiO₂ film may be as thin as possible; that is approximately between 1 nm and 10 nm inclusive.

Thanks to the above structure, the light attenuation filter 36 can successfully maintain its insulation properties even though a source of leakage is found in the solid electrolyte layer 34 made of transition metal oxide. The maintained insulation properties contribute to reducing variation in transmittance in a plane of the light attenuation filter 36, securing repeatability of the transmittance, and maintaining the transmittance for a longer period. Such features make it possible to implement a solid-state imaging device including a high-yield and high-performance light attenuation filter.

### Embodiment 5

Embodiment 5 describes a solid-state imaging device whose solid electrolyte layer is made of a different material. A comparison shows that the solid-state imaging device according to Embodiment 5 differs from the solid-state imaging devices 100 and 110 according to Embodiment 1 only in the material for the solid electrolyte layer included in the light attenuation filter. Hereinafter, the same points between a light attenuation filter in Embodiment 5 and the light attenuation filter 16 shall be omitted. Only the differences therebetween shall be described.

A solid-state Imaging device 140 according to Embodiment 5 includes a light attenuation filter 46.

In the stacking order, the light attenuation filter 46 includes a transparent electrode 31, a solid electrolyte layer 47, the active-material layer 33, and the transparent electrode 32.

The solid electrolyte layer 47 is made of one of metal oxides, such as ZrO₂, Ta₂O₅, Cr₂O₃, V₂O₅, Nb₂O₅, and HfO₂. Such metal oxides include any one of Li, Na, and Ag. An exemplary material for the solid electrolyte layer 47 is LiV₂O₅. The ion conduction medium for the light attenuation filter 46 according to Embodiment 5 is hydrogen ions. From the viewpoint of the device reliability, however, the medium does not have to be hydrogen. The principle that the active-material layer 33 changes the transmittance is that electrons are injected into the active-material layer 33 along with ions attracted thereto, causing reduction reaction which involves reduction in the atomic valence of the central metal ion. Any ions may be injected as far as the ions can move in a solid substance. It is noted that the element needs to diffuse into the solid substance and be excellent in controllability. Hence the most suitable element is hydrogen since the atomic radius and the ionic radius of hydrogen are shortest. In terms of a device operation, in contrast, hydrogen is not always most suitable due to an influence on its reliability caused by operation environment and a process yield. For example, an operation in a high temperature can cause deaeration.

In Embodiment 5, Li⁺ is used as ions. Along with H, Li has a short ionic radius and significantly small ionization potential. Thus Li easily causes oxidation-reduction reaction. Furthermore, the above-described technique to introduce hydrogen, such as the liquid immersion by the hydrogen annealing or by acid has been described before, faces a difficulty in quantitatively controlling the amount of hydrogen to be introduced. From this aspect, Li can be used as a source of a solid-state material source for a depositing device. Hence Li can be quantitatively introduced.

The amount of Li to be introduced may be non-stoichiometric as a chemical composition. Since Li is used as a solid-state material source for the depositing apparatus, the Li in Embodiment 5 is LiV₂O₅ expressed in a chemical formula.

Moreover, Li is the ionic element used in Embodiment 5; instead, an alkali metal which easily causes oxidation reduction may be used as far as the element of the ionization potential is small. It is noted that, for the diffusion of ions, the radius of each ion should be short. Thus Li or Na is suitable. In the case of a multi-charged ion, the electrostatic potential of the ion itself is large, and activation energy for the ion movement is significantly large. Hence, the ion movement by an electric field is difficult. Thus the atomic valence is preferably 1, and AgV₂O₅ including Ag may be used instead of Li.

Moreover, as stable solid electrolyte materials which include Li or Ag, metal oxides such as ZrO₂, Ta₂O₅, Cr₂O₃, V₂O₅, Nb₂O₅, and HfO₂ are suitable. Such features and the use of metal ions as an ion conduction medium make it possible to deposit compositionally-controlled solid electrolyte in a quantitative manner. This contributes to forming a light attenuation filter having high homogeneity. Consequently, the transmittance of the light attenuation filter can be controlled more accurately, and a high-yield and high-performance solid-state imaging device can be implemented.

As described in Embodiments 1 to 5, the solid-state imaging device and the imaging apparatus according to the present invention have a wide dynamic range, and can contribute to a sophisticated and high-performance small camera having a light amount adjusting capability.

Specifically, the solid-state imaging device including the light attenuation filter of the present invention and the imaging apparatus including the signal processing device of the present invention can attenuate, using the light attenuation filter, the amount of light which arrives at a pixel block whose region is saturated with luminance signals. Hence even though the saturation capacity decreases because of a smaller pixel size, the solid-state imaging device and the imaging apparatus can implement a wide dynamic range, and adjust the amount of light under the high lighting intensity without a mechanical aperture. Such features contributes to implementing a small solid-state imaging device which can capture an object under high lighting intensity, have a wide dynamic range, and obtain finer images.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

It is noted that Embodiment 1 exemplifies a CMOS solid-state imaging device; however, the present invention shall not be defined only for the CMOS solid-state imaging device. In the present invention, a CCD solid-state imaging device is also as effective as the CMOS one.

### INDUSTRIAL APPLICABILITY

The present invention is useful for digital cameras, and is most suitable for solid-state imaging devices and cameras which need to have a wide dynamic range and obtain high quality images.

1. A solid-state imaging device including an imaging region having pixel units two-dimensionally arranged, each of the pixel units including a photoelectric converting device formed on a semiconductor substrate, and the solid-state imaging device comprising:
an interlayer film which is made of a dielectric and formed above the photoelectric converting device;
a light attenuation filter which is formed above the interlayer film for each of the pixel units or for each of pixel blocks, and changes a transmittance of light when a voltage is applied to the light attenuation filter, the pixel blocks each including a plurality of the pixel units; and
a switching transistor which is formed in the semiconductor substrate for each of the light attenuation filters, and connects or disconnects a path for applying the voltage to the light attenuation filter.

2. The solid-state imaging device according to claim 1,
wherein the light attenuation filter includes:
a lower transparent electrode which is stacked on the interlayer film made of the dielectric;
a solid electrolyte layer and an active material layer which are stacked over the lower transparent electrode; and
an, upper transparent electrode which is stacked on one of the solid electrolyte layer and the active material layer whichever is provided above,
wherein the solid electrolyte layer is made of insulating dielectric, and attracts and releases ions when the voltage is applied to the lower transparent electrode and the upper transparent electrode, and
in the active material layer, an absorbing spectrum changes according to the attraction and the release of the ions caused by the application of the voltage.

3. The solid-state imaging device according to claim 2,
wherein the active material layer is an amorphous film made of one of WO₃, MoO₃, and IrO₂.

4. The solid-state imaging device according to claim 2,
wherein the solid electrolyte layer includes hydrogen and is made of at least one of ZrO₂, Ta₂O₅, Cr₂O₃, V₂O₅, SiO₂, Nb₂O₅, and HfO₂.

5. The solid-state imaging device according to claim 2,
wherein the solid electrolyte layer is made of one of metal oxides, such as ZrO₂, Ta₂O₅, Cr₂O₃, V₂O₅, Nb₂O₅, and HfO₂, the metal oxides including at least one of Li, Na, and Ag.

6. The solid-state imaging device according to claim 2,
wherein the light attenuation filter further includes a thin insulating layer provided between the solid electrolyte layer and the active material layer, and
the thin insulating layer is made of one of SiO₂, SiON, and SiN.

7. The solid-state imaging device according to claim 1,
wherein the solid-state imaging device is placed in an airtight package which is filled with N₂ or a noble gas.

8. An imaging apparatus comprising:
the solid-state imaging device according to claim 1; and
a signal processing device which adjusts an amount of light entering the imaging region,
wherein the signal processing device includes:
a determining unit configured to previously determine before exposure whether or not luminance signals provided from the pixel units saturate; and
a transmittance control unit configured to, in the case where the determining unit determines that the luminance signals saturate, electrically control a transmittance of the light attenuation filter so as to prevent the luminance signals in the exposure from saturating, by setting before the exposure a voltage to be applied to the light attenuation filter.

9. The solid-state imaging device according to claim 8,
wherein the solid-state imaging device includes the light attenuation filter provided for each of pixel blocks which includes pixel units arranged in a two-by-two matrix,
the signal processing device further includes a specifying unit configured to specify a region at which saturated signals are provided, based on previously-obtained intensity distribution of the luminance signals that are observed in the imaging region, and
the transmittance control unit is configured to electrically control the transmittance of the light attenuation filter so as to prevent the luminance signals in the exposure from saturating, by setting before the exposure the voltage to be applied to the light attenuation filter provided for each of the pixel blocks, the luminance signals being observed in a pixel block included in the pixel blocks and the specified region.

10. The solid-state imaging device according to claim 8,
wherein the solid-state imaging device includes pixel blocks each including pixel units arranged in a two-by-two matrix,
the pixel blocks are arranged in a Bayer pattern, and each including a G1 pixel unit and a G2 pixel unit which obtain a green signal, an R pixel unit which obtains a red signal, and a B pixel unit which obtains a blue signal,
the light attenuation filter is provided only over the G1 pixel unit and the G2 pixel unit,
the determining unit is configured to previously determines before the exposure whether or not luminance signals provided from the G1 pixel unit and the G2 pixel unit saturate, and
the transmittance control unit is configured to, in the case where the determining units determine that the luminance signals saturate, electrically control the transmittance of the light attenuation filter so as to prevent the luminance signals in the exposure from saturating, by setting before the exposure the voltage to be applied to the light attenuation filter.
